(19) United States
(12) Patent Application Publication
(10) Pub. No.: US 2024/0203695 A1
(43) Pub. Date: Jun. 20, 2024

(54) FAST GAS SWITCHING

(71) Applicant: Applied Materials, Inc., Santa Clara, CA (US)

(72) Inventors: Toan Tran, San Jose, CA (US); Yen-Kun Wang, Santa Clara, CA (US); Reyn Wakabayashi, Sunnyvale, CA (US); Steve Babayan, Los Altos, CA (US); Wayne Wan, San Jose, CA (US)

(21) Appl. No.: 18/083,372

(22) Filed: Dec. 16, 2022

(51) Int. Cl. H01J 37/32; H01L 21/3065; H01L 21/311

(52) U.S. Cl. CPC H01J 37/32449; H01J 37/32972; H01L 21/3065; H01L 21/31116; H01J 2237/3346

(57) ABSTRACT

A system including a chamber enclosing a processing region, a substrate support within the chamber and configured to retain a substrate in the processing region, a gas distribution manifold coupled to the chamber to introduce first and a second etching gases from the gas distribution manifold using first and second inlets, a first gas distribution channel coupled configured to selectively switch between directing the first etching gas along a first gas flow path towards the processing region, and directing the first etching gas towards a vent, and a second gas distribution channel configured to selectively switch between directing the second etching gas towards the vent, and directing the second etching gas along a fourth gas flow path towards the processing region, and a flow ratio controller operatively coupled to the first and second gas distribution channels and configured to direct the first or second etching gases towards the processing region.

### TECHNICAL FIELD

This specification relates to semiconductor systems, processes, and equipment.

### BACKGROUND

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

This specification describes technologies for fast gas switching in a plasma-based semiconductor processing chamber. These technologies generally involve flowing an etching gas mixture to form a plasma in a processing region of a chamber. Charged particles of the plasma are drawn towards an exposed surface of a substrate retained in the processing region of the chamber to perform an etching process on the exposed surface. Compositions of etching gas mixtures can be selected to etch different layer compositions, for example, a first etching gas mixture to etch silicon oxide (SiO) and a second etching gas mixture to etch silicon nitride (SiN). A semiconductor processing chamber can include one or more (e.g., two or more) processing regions, each with a respective substrate holder to retain a respective substrate and individually controllable etching gas mixtures to form a respective plasma in the processing regions.

In general, one innovative aspect of the subject matter described in this specification can be embodied in a system for semiconductor processing. The system includes a chamber enclosing a first processing region. The system includes a first substrate support within the chamber that is configured to retain a first substrate in the first processing region of the chamber. The system includes a gas distribution manifold, where the gas distribution manifold is operatively coupled to the chamber to introduce a first etching gas comprising one or more gases from the gas distribution manifold using a first inlet into the chamber and a second etching gas including one or more gases from the gas distribution manifold into the chamber using a second inlet. The system includes a first gas distribution channel coupled to the first inlet and configured to selectively switch between directing the first etching gas along a first gas flow path towards the first processing region within the chamber, and directing the first etching gas along a second gas flow path towards a vent. The system includes a second gas distribution channel coupled to the second inlet and configured to selectively switch between directing the second etching gas along a third gas flow path towards the vent, and directing the second etching gas along a fourth gas flow path towards the first processing region within the chamber. The system includes a first flow ratio controller (FRC) operatively coupled to the first gas distribution channel and the second gas distribution channel and is configured to direct the first etching gas or the second etching gas towards the first processing region.

Other embodiments of this aspect include corresponding methods, computer systems, apparatus, and computer programs recorded on one or more computer storage devices.

In general, another innovative aspect of the subject matter described in this specification can be embodied in methods of semiconductor processing. The methods include flowing a first etching gas including one or more gases from a gas distribution manifold through a first gas flow path and towards a first flow ratio controller of a semiconductor processing chamber while processing a first substrate supported by a first substrate support, where the first flow ratio controller is operable to direct the first etching gas toward a first processing region. The methods further include flowing a second etching gas including one or more gases from the gas distribution manifold through a third gas flow path and towards a vent while processing the first substrate supported by the first substrate support and while the first etching gas is flowing through the first gas flow path. The methods further include switching, based on a first switching trigger, a flow of the first etching gas to a flow of the second etching gas in the first processing region including switching the flow of the first etching gas through a second gas flow path and towards the vent. The methods further include switching the flow of the second etching gas through a fourth gas flow path and towards the first flow ratio controller while the first etching gas is flowing through the second gas flow path and towards the vent, where the first flow ratio controller is operable to direct the second etching gas toward the first processing region.

Other embodiments of this aspect include corresponding systems, computer systems, apparatus, and computer programs recorded on one or more computer storage devices, each configured to perform the actions of the methods.

The subject matter described in this specification can be implemented in these and other embodiments so as to realize one or more of the following advantages. Independent control of etching processes for the two or more processing regions can improve throughput and selectivity of the etching being performed for each of the substrates in the chamber. Separately implementable gas switching for a chamber including two or more processing regions with a shared gas manifold can accommodate (e.g., compensate) for variations in the etching processes of each processing region without forcing a delay of subsequent etching processes for one or more other processing regions in the chamber. Minimizing a delay of subsequent etching processes can reduce over-etching of a wafer that has completed an etching process by facilitating the next etching process to proceed while another wafer is still undergoing the previous etching process. Use of gas flow restricting components in shared gas lines between two or more processing regions in a chamber can reduce crosstalk between the two or more processing regions and reduce effects of switching etching gas in fewer than all the processing regions at a time. Arranging a gas switching point closer to a processing region for generating a plasma can reduce a switching time between etching gases and decrease a lag for establishing a threshold concentration of the etching gas. Shorter stabilization times for switching over to a new etch chemistry in the plasma can result in improved etch characteristics. For example, decreased stabilization time can result in improved etch precision and higher fidelity features.

Although the remaining disclosure will identify specific etching processes using the disclosed technology, it will be readily understood that the systems and methods are equally applicable to a variety of other processes as can occur in the described chambers. Accordingly, the technology should not be considered to be so limited as for use with the described etching processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example plasma processing chamber.

FIG. 2 shows a schematic cross-sectional partial view of an example plasma processing chamber including gas switching.

FIGS. 3A-3D depict an example process for implementing gas switching methods for a tandem plasma processing chamber.

FIGS. 4A-4B depict an example process for calibrating the flow restriction nodes of a plasma processing chamber.

FIG. 5A depicts an example plot of processing data collected by a characterization device of a plasma processing chamber.

FIG. 5B depicts an example plot of an OES system monitoring an etching process.

FIG. 6 depicts a partial control flow of gas switching methods.

FIGS. 7A-7C depict example cross-sectional schematic views of portions of various example plasma processing chambers.

FIG. 8 shows a flow diagram of an example process for a plasma processing chamber including gas switching.

Like reference numbers and designations in the various drawings indicate like elements.

### DETAILED DESCRIPTION

The present specification provides improved methods and assemblies for controlling gas flow into a process chamber, such as a semiconductor process chamber, or the like. Embodiments of the present disclosure provide fast gas switching assemblies and methods for processing chambers (e.g., a capacitive-coupled plasma chamber) suitable for performing plasma-based etching processes (e.g., also referred to as “etch processes”). Two or more substrates can be processed in parallel in separate processing regions (e.g., processing stations) within a same chamber can be supplied with etching gases (e.g., also referred to as “etch gases”) by a shared gas panel.

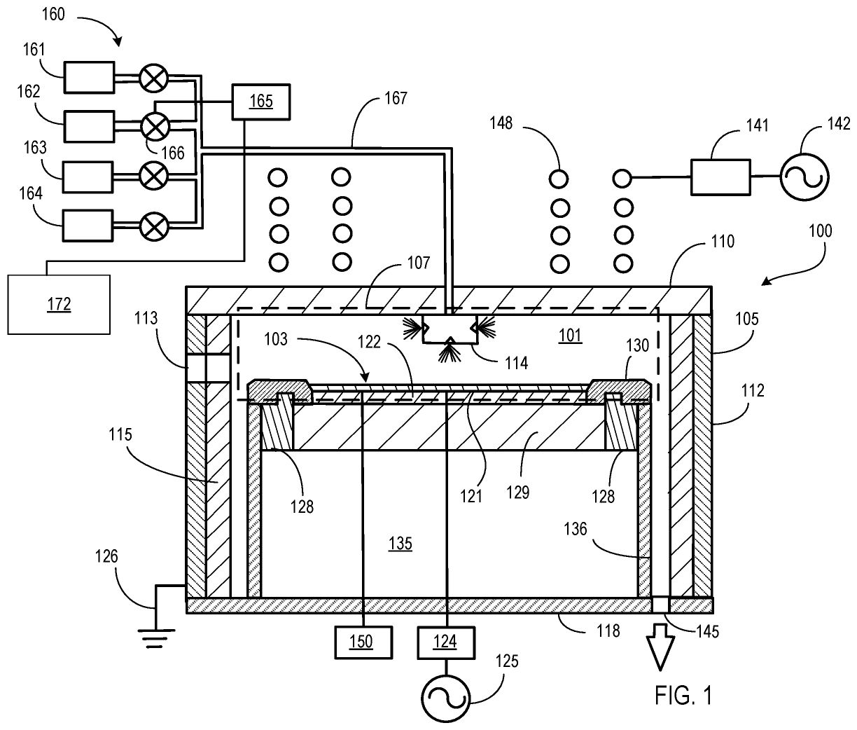

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by an RF power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid assembly 110 can include a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 103 and/or above the substrate 103 can be used to capacitively couple RF power to the process gases to maintain the plasma within the chamber volume 101. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

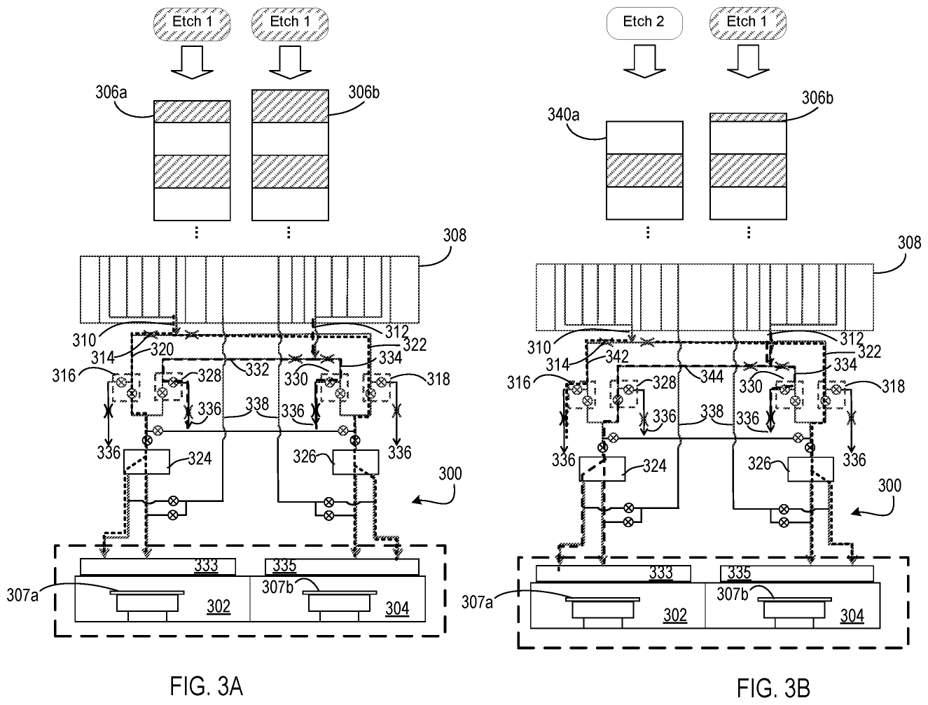

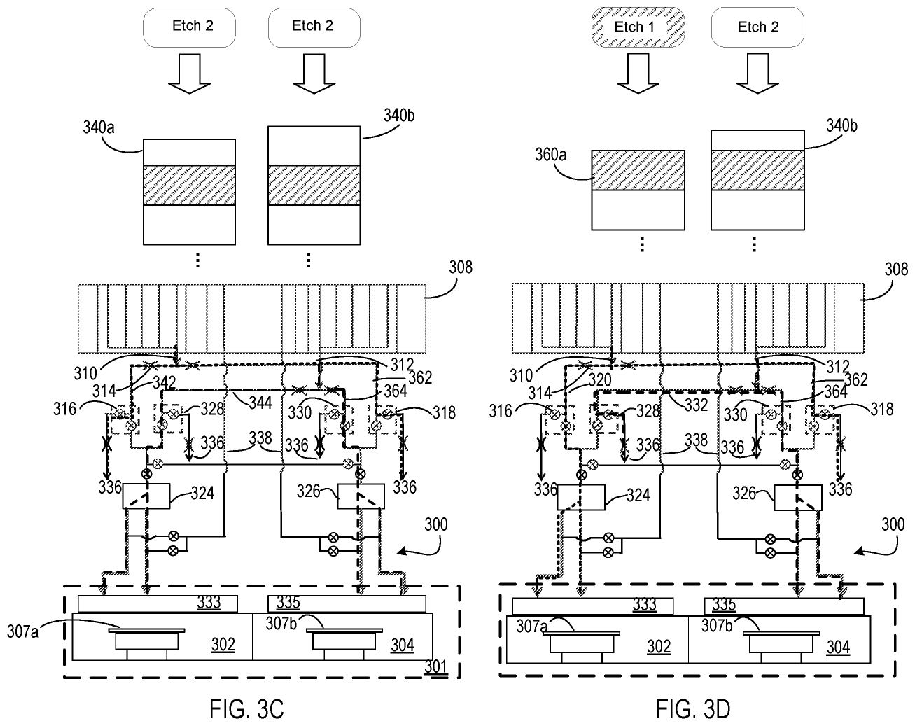

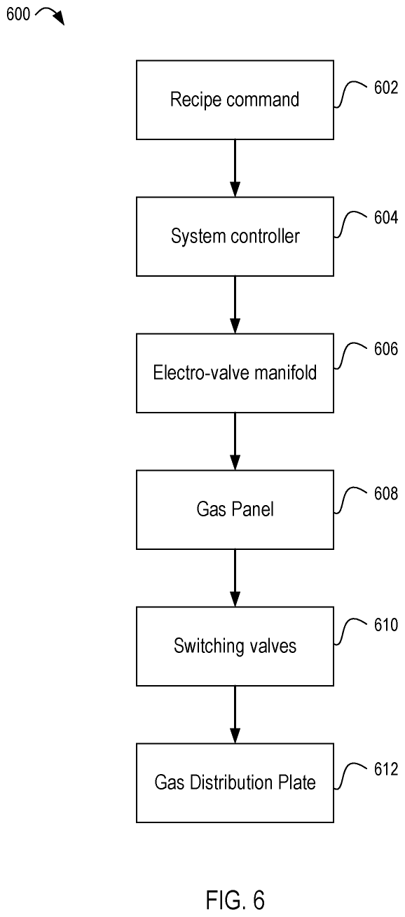

In some embodiments, controller 165 can determine to switch an etching gas mixture to a next etching gas mixture, e.g., to etch a next layer of a layer structure, based in part on processing data collected by characterization device 172. A trigger for switching to a next etching gas mixture can depend in part on signal characteristic(s) collected by the characterization device 172, e.g., relative intensities of monitored wavelengths. Further details related to triggering switching of etching gas mixtures are discussed with reference to FIGS. 3A-3B, and 6.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

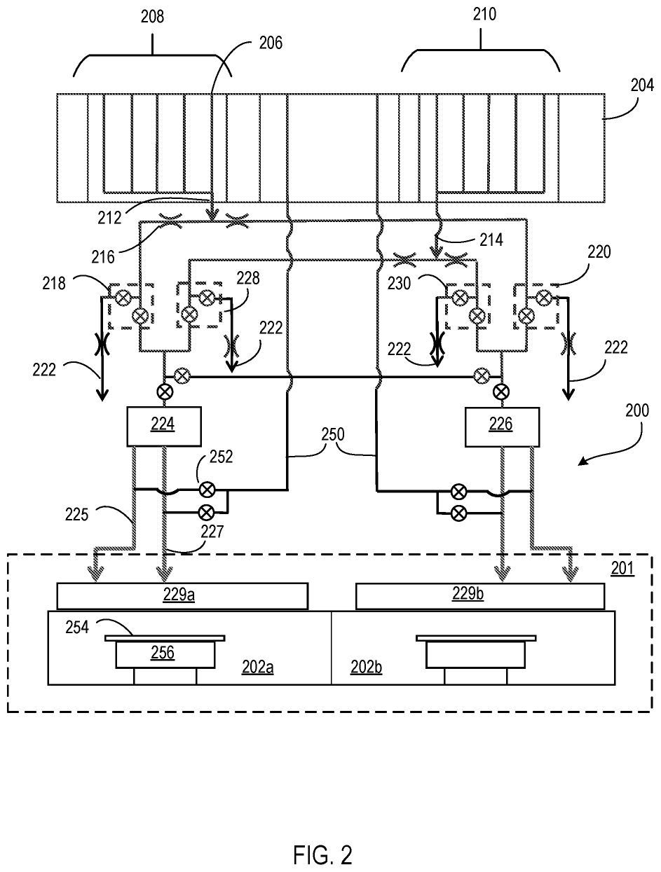

In some embodiments, a process chamber is a tandem process chamber including two processing regions within a processing chamber for performing parallel processing of two substrates. FIG. 2 depicts an example cross-sectional view of a portion of a tandem plasma processing chamber 200. A tandem plasma processing chamber 200 includes two processing regions 202a, 202b, e.g., two processing stations, within a chamber volume 201 where each processing region is configured with components described herein with respect to processing region 107 in FIG. 1.

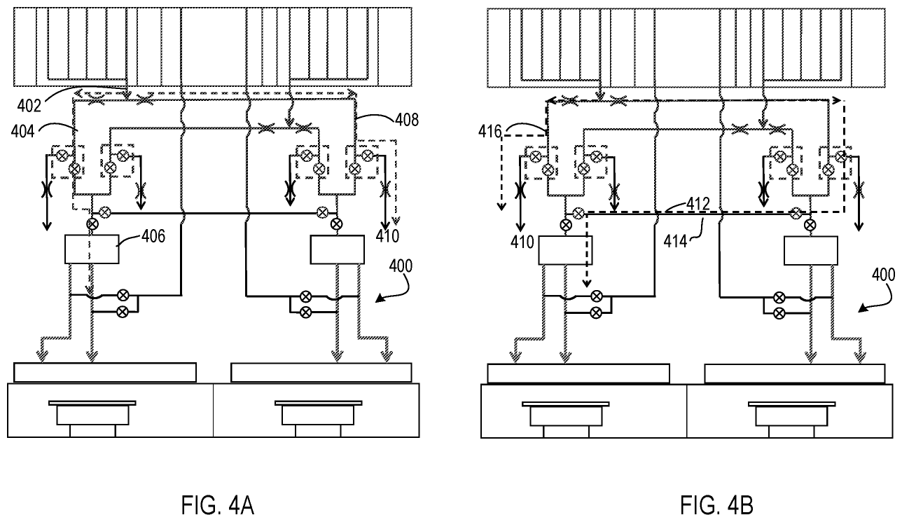

Tandem plasma processing chamber 200 includes a gas panel 204 including gas sources, e.g., gas source 206. Gas panel 204 can be configured to include at least two sets of gas sources, each set of gas sources selected for a type of etch chemistry. For example, gas panel 204 can include a first set of gas sources 208 selected for performing oxide-based etches and a second set of gas sources 210 selected for performing nitride-based etches. Each gas line 212, 214 is coupled to the set of gas sources 208, 210 respectively. Gas lines 212, 214 are divided (e.g., split) between the processing regions 202a, 202b, where gas line 212 is configured to direct a flow of a first etching gas and gas line 214 is configured to direct a flow of a second etching gas from the gas panel 204. The division of each of the gas lines 212, 214 can be regulated using flow restriction node(s), e.g., flow restriction node 216. A flow restriction node can be, for example, an orifice, a valve (e.g., needle valve), a flow ratio controller (FRC), two or more mass flow controllers (MFC) working in tandem, or another type of active or passive flow restricting component, as described in further detail below with reference to FIGS. 4A-4B.

Each portion of the divided gas line 212 directs a portion (e.g., about 50%) of the first etching gas flow towards a respective processing region 202a, 202b, where a set of switching valves 218, 220 corresponding to the first etching gas are configured switch flow of gas between (i) vent (e.g., a foreline) 222 and (ii) along a respective gas flow path to a corresponding flow ratio controller (FRC) 224, 226.

Each portion of the divided gas line 214 directs a portion of the second etching gas flow towards a respective processing region 202a, 202b, where a set of switching valves 228, 230 corresponding to the etching gas are configured switch flow of gas between (i) vent (e.g., a foreline) 222 and (ii) along a respective gas flow path to a corresponding flow ratio controller (FRC) 224, 226.

The FRCs 224, 226 can divide (e.g., split) flow of gas along two or more flow paths. The FRCs 224, 226 can be configured to adjust a ratio of gas flow into each of the divided paths, for example, where a first path has less flow than a second path. For example, an FRC 224, 226 can divide gas flow between an edge flow and a center flow. A divided gas flow ratio between an edge flow and a center flow can range, for example, from about 5% to about 95%. Gas flow from FRCs 224, 226 can be introduced into a respective processing region 202a, 202b within the chamber volume 201 using inlets to gas distribution plates (GDPs) 229a, 229b (e.g., nozzle 114). Gas distribution plates 229a, 229b can introduce the etching gas through multiple openings (not shown) in the GDPs 229a, 229b. GDPs 229a, 229b includes gas plenums (not shown) to supply etching gas to a backside of the GDPs, where an opening size of the multiple openings can be sufficiently small to generate a pressure drop across the GDP and provide a uniform gas flow through the multiple openings for a given region (e.g., edge region or center region) of the GDP.

At times, an edge region and a center region of the gas delivery GDP 229a, 229b can have different gas paths and receive variable ratios of flow rates of the etching gas from FRCs 224, 226, respectively. For example, variable ratios of flow rates of the etching gas provided by an FRC to an edge region 225 and a center region 227 of the GDP can be utilized to control for radial uniformity of an etching process. Plasmas can be established in processing regions 202a, 202b, for example, using the processes described with respect to FIG. 1. The reactive species of the plasmas are directed toward the exposed surfaces of respective wafers, e.g., substrate 254 (e.g., also referred to herein as substrate) supported by substrate supports, e.g., substrate support 256, in the chamber to perform etching process(es).

In some embodiments, plasma processing chamber 200 includes one or more independent gas injection (IGI) lines 250, (e.g., a gas injection channel(s)), coupled to the gas panel 204 and configured to direct an injection gas into a processing region using the GDP 229a, 229b. Injection gas can be, for example, 02. Injection gas can be used, for example, to supplement a radial uniformity of an etching process. Injection gas flow rates can be substantially lower than flow rates of the etching gases. For example, injection gas flow rates can range from about 1% to about 20% of etching gas flow rates. IGI lines 250 can include valves, e.g., valve 252, operable to control a flow of the injection gas to an edge region and/or center region of a GDP 229a, 229b.

In some embodiments, switching valves 218, 220, 228, 230 can be used to maintain a charged line between the gas panel 204 and the switching valves 218, 220, 228, 230 for an etching gas that is not currently being used to establish the plasma. By venting the unused etching gas rather than shutting the gas off at the gas panel, the ramp up time to transition between etching gases during a switch is reduced, e.g., reduce by 3-5 times.

In some embodiments, switching valves 218, 220, 228, 230 can be arranged adjacent to an insertion point into the chamber volume 201 to minimize a length of a gas flow path between switching valves and the FRC 224, 226 coupled to the GDP 229a, 229b introducing the gas to the processing region 202a, 202b. Minimizing the length of the gas line between a respective switching valve and the FRC reduces an amount of time to backfill the lines and reduces a transition time to establish the plasma using the next etching gas. For example, minimizing the length of the gas line between respective switching valves and the FRC reduces the transition time to establish the plasma with the next etching gas by about 1 to about 2 seconds.

In some embodiments, a plasma etching process can be performed on layer structures including layers having different layer compositions. For example, a layer structure can include alternating layers of two material compositions, e.g., SiO and SiN. Each layer composition can have a respective etch chemistry having high selectivity for etching the layer composition. The etch chemistries for each layer composition can have one or more of the same gas(es) in the etching gas mixture. The etch chemistries for each layer composition can have one or more different gas(es) in the etching gas mixture. The etching gas mixtures forming the plasma in a processing region can be selected based in part on a layer composition of an exposed layer (e.g., top layer) of the layer structure that is being etched.

At times, parallel etching process(es) performed on two or more substrates in respective processing regions of the chamber can have different durations (e.g., time to complete an etching process). Variations in duration of a same etching process between substrates in different processing regions can occur, for example, due to (i) non-uniformities of each substrate, (ii) variation in hardware tolerances, (iii) variation in gas flow of process (etch) gas(es) or (iv) any combination of (i) to (iii). As a result, respective times to perform a same etch on corresponding layers of nominally identical layer structures on two different substrates may be different. The different durations can result in a first substrate having completed a first etching process and continuing to over-etch while waiting for the second substrate to complete the first etching process before switching to a second etching process. In order to reduce (e.g., minimize or eliminate) an over-etch of the first substrate, the first substrate can be switched to the second etching process while the first etching process is still running for the second substrate. Gas switching where each processing region can have the same or different etching gas at a particular time can be implemented using the plasma processing chamber described with respect to FIG. 2.

In some embodiments, as depicted in FIG. 2, a tandem chamber can be coupled to a shared gas panel with shared gas lines originating from one feed and split between two processing regions. In instances where an etching process completes for one substrate before the etching process completes on another substrate, switching etching gases for the completed processing region can affect gas flow/gas pressure for each other processing region (e.g., through a back pressure effect). To reduce effects of gas switching for fewer than all processing regions at a time, a divert function can be implemented to divert a flow to the vent (e.g., foreline) but without having to shut off valve(s) associated with the etching gas from the gas panel.

FIGS. 3A-3D depict an example process for implementing gas switching methods for a tandem plasma processing chamber 300, e.g., plasma processing chamber 200 described in FIG. 2. In FIG. 3A, a first etching gas is introduced to a first processing region 302 and second processing region 304 to etch first layers 306a, 306b of a first layer composition of each wafer 307a, 307b. A first etching gas is introduced from the gas panel 308 through gas line 310 that is divided between the first and second processing regions. A second etching gas is introduced from the gas panel 308 through gas line 312 that is divided between the first and second processing regions. Flow restriction nodes, e.g., flow restriction node 314, can be adjusted to control a flow rate of each of the divided flow paths, e.g., to ensure each of the flow paths are in a low flow (e.g., choked flow) regime.

Switching valves 316, 318 are set to direct the first etching gas towards respective FRCs 324, 326 through the first flow path 320 and third flow path 322. Each FRC 324, 326 divides the first etching gas into an edge component and a center component. The first etching gas is introduced into the tandem chamber body 301 through gas distribution plates 333, 335 for establishing plasmas within the first and second processing regions to perform the etching process of the first layer 306 of a substrate. Switching valves 328, 330 are set to direct the second etching gas towards a vent (e.g., foreline) 336 using a second flow path 332 and a fourth flow path 334. In some embodiments, one or more IGI lines 338 can direct injection gas (e.g., 02) towards one or both of the processing regions 302, 304. As depicted in FIG. 3A, an etching process for a first wafer in the first processing region progresses more quickly than an etching process for a second wafer in the second processing region. (e.g., as indicated by respective thicknesses of each of the first layer)

In FIG. 3B, the first etching process using the first etching gas has completed for the first wafer while the first etching process has not completed for the second wafer such that a portion of the first layer 306b for the second wafer remains to still be etched. The second etching process is therefore initiated only for the first wafer in the first processing region by selectively switching the etching gas delivered to the first processing region 302 while maintaining the current etching gas being delivered to the second processing region 304 to complete the first etching process. A second etching process is initiated on a second layer 340a of a second composition using the second etching gas in the first processing region 302. Switching valves 316 are set to direct the first etching gas towards the vent 336 along a fifth flow path 342 and switching valves 328 are set to direct the second etching gas towards the FRC 324 along sixth flow path 344, where the FRC 324 divides the flow of the second etching gas towards the first processing region through gas distribution plate 333 to establish the plasma.

In FIG. 3C, the first etching process using the first etching gas has completed for the second wafer, which triggers the initiation of the second etching process for the second wafer. The second etching process is initiated on a second layer 340b of the second composition using the second etching gas in the second processing region 304. Switching valves 318 are set to direct the first etching gas towards the vent 336 along seventh flow path 362 and switching valves 330 are set to direct the second etching gas towards the FRC 326 along eighth flow path 364, where the FRC 326 directs the second etching gas towards the second processing region through gas distribution plate 335 to establish the plasma.

In FIG. 3D, the second etching process using second etching gas has completed for the first wafer while the second etching process has not completed for the second wafer such that a portion of the second layer 340b for the second wafer still remains to be etched. A third etching process is therefore initiated only for the first wafer in the first processing region 302 by selectively switching the etching gas delivered to the first processing region 302 while maintaining the current etching gas being delivered to the second processing region 304 to complete the second etching process. The first processing region 302 is set up to perform a third etching process on a third layer 360a of the first composition using the first etching gas. Switching valves are set to direct the first etching gas towards FRC 324 along the first flow path 320, and switching valves 328 are set to direct the second etching gas towards the vent 336 along second flow path 332, where FRC 324 directs the first etching gas towards the first processing region 302 through gas distribution plate 333 to establish the plasma.

At times, switching between a first etching gas and a second etching gas for one of the two or more processing regions can result in a change in line pressure for one or more gas lines from the gas panel. For example, switching a first flow path to a vent can affect a pressure in a third flow path due to the shared upstream gas line from the gas panel. In another example, switching a second flow path to a vent can affect a pressure in a fourth flow path due to the shared upstream gas line from the gas panel. A change in line pressure can be, for example, a drop in downstream pressure in a portion of the shared gas line. To reduce a crosstalk between the gas lines corresponding to the first processing region and the second processing region, flow restriction nodes can be utilized. The flow restriction nodes can be operable to (i) create low flow conditions, for example, a choked flow regime in the gas lines, and (ii) to reduce downstream pressure fluctuations, e.g., reduce crosstalk, between the two processing regions. Flow rates in the low flow conditions, e.g., choked flow regime, can range from about 1000 standard cubic centimeters per minute (sccm) to about 3000 sccm.

As depicted in FIG. 2, flow restriction nodes can be arranged with respect to the gas lines prior to the switching valves to reduce a dependence of the flow of gas on downstream pressure and to additionally divide the flow of the gas per a requested ratio (e.g., evenly) between the processing regions. A flow restriction node can include, for example, a calibrated orifice, a valve (e.g., needle valve), an FRC, a mass flow controller (MFC), or another flow restricting passive or active component. A type of flow restriction node and/or an implementation of the flow restriction node can be selected to reduce a buildup of pressure behind the flow restriction node, e.g., to prevent exceeding a maximum upstream pressure. In some embodiments, flow restriction nodes can be dynamically tunable to adjust to various flow regimes. For example, flow restriction nodes can be tuned for various flow regimes during an etching process(es). Active control of division of a flow of gas through the flow restriction node(s) can be performed by active flow restriction components. For example, by two MFCs or FRCs in data communication with each other (or with a controller 165 operable to adjust a flow through each of the MFCs or FRCs). A controller, e.g., controller 165, can be in data communication with a variable flow restriction node to adjust flow conditions for the flow restriction node.

In some embodiments, calibrating the flow restriction nodes, e.g., flow restriction nodes 216, 314, can be performed to optimize a performance of the flow restriction nodes, e.g., to generate the choked flow regime and/or reduce downstream pressure fluctuations. FIGS. 4A-4B depict an example process for calibrating the flow restriction nodes of a plasma processing chamber 400, e.g., plasma processing chamber 200. In FIG. 4A, a flow of the first etching gas through a first line 402 is directed along a first gas flow path 404 toward FRC 406 and along a fourth gas flow path 408 toward a vent 410. In FIG. 4B, a bypass line 412 is used to draw the first etching gas along the third gas path 414 through the bypass line 412 and toward the FRC 406 while the first etching gas is directed along a second gas flow path 416 toward the vent 410. In this way, variations in FRC operation can be removed (e.g., minimized) from a calibration process, and a calibration of each of the flow restriction nodes on the first gas line can be calibrated to maintain a downstream pressure of the divided line while one portion of the gas line is directed to the vent (e.g., foreline).

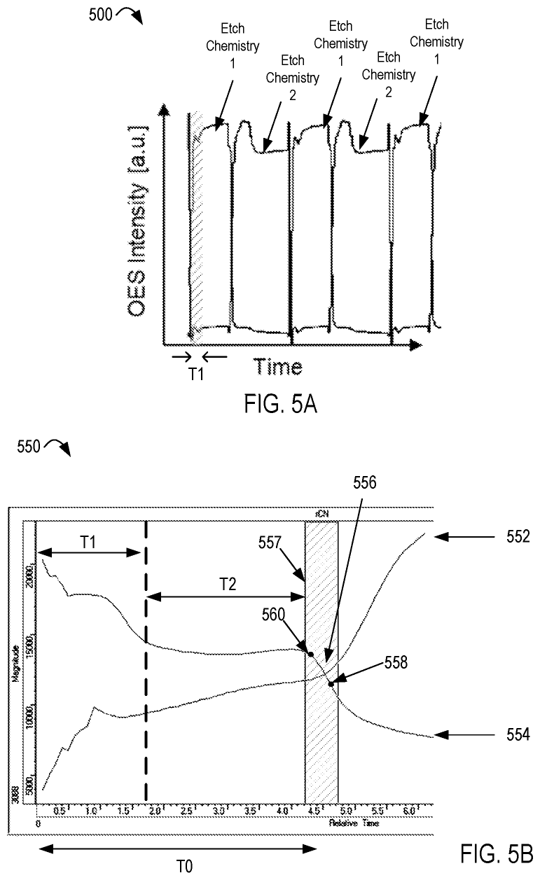

At times, switching between a first etching gas and a second etching gas can result in a stabilization time within the processing region before a threshold pressure (e.g., threshold concentration) of the second etching gas is established in the processing region. FIG. 5A depicts a plot 500 of example processing data collected by an OES system of a plasma within a processing region. Two wavelengths corresponding to the two etch chemistries are monitored over time during etching processes (e.g., of an alternating layer structure). As each etching gas is introduced into the processing region, a ramp up time, e.g., ramp up time T1, corresponding to a period of time to establish the plasma with the etching gas is observable by monitoring an intensity of the monitoring wavelength for the etch chemistry. A slope of the intensity curve can be used as a metric to define a stability of the plasma, where a stabilization time can be determined using process optimization to identify a slope of the curve corresponding to plasma stabilization. The ramp up time can translate into a stabilization time for the etching process for the etching gas, e.g., to achieve a nominal etch rate for the etching process. Using the gas switching methods described in this specification can reduce a ramp up time by reducing a length of gas line that needs to be backfilled before the next etching gas is introduced to the processing region.

In some embodiments, to compensate for a stabilization time for the etching processes between the first etching gas and the second etching gas, a switchover trigger between the first etching gas and the second etching gas can be determined. A controller, e.g., controller 165, can use processing data generated by characterization device, e.g., characterization device 172, to determine a switchover point and trigger a switchover process between the first and second etching gases, e.g., to initiate a next etching process. The switchover process can include providing by the controller 165 and to the switching valves, control signals to selectively open or close respective switching valves to configure one or more of the processing regions for the next etching process.

FIG. 5B depicts an example plot 550 of an OES system monitoring an etching process. A first signal 552 and a second signal 554 each correspond to an intensity of a characteristic wavelength for a respective etching process, e.g., an oxide-based etch and a nitride-based etching process. A process time TO for each etching process includes a stabilization time T1 and an etching time T2. At times, the stabilization time T1 also includes etching of the layer, but at a different (e.g., slower) etching rate than the etching rate during the etching time T2. A trigger point 556 indicative of a completion of each etching process (e.g., when a layer is substantially or fully etched) can be determined within a switchover period 557 as a threshold change in slope of the signal curve. For example, the trigger point 556 can correspond to a threshold value of the slope derivative of the signal curve. The controller 165 can determine the trigger point for the layer by determining when a value for the slope derivative meets a switchover threshold value and select to trigger a switchover of etching gases to proceed to a next etching process in response. In some embodiments, a switchover point 558 can correspond to a time period that is off-set from the trigger point 556, e.g., before or after the trigger point 556. For example, a target etching process can include a slight over-etch such that the switchover point 558 can be after the trigger point 556 to facilitate an over-etch of the layer. In another example, a target etching process can include an under-etch to accommodate a stabilization time for the next etching gas, such that the switchover point 560 is before the trigger point 556.

In some embodiments, controller 165 can use control processes to determine trigger points in part based on the processing data and select timing for switching over to a next etching process, e.g., when to switch valve configuration to establish the next etching gas plasma in the processing region. Control processes can include, for example feedforward and/or feedback control loops to implement the methods described herein. Controller 165 can use one or more machine-learning models for performing the control methods described herein, e.g., to infer trigger points and/or switchover points based in part on processing data collected by the characterization device 172.

In some embodiments, controller 165 is operable to implement plasma processing systems and methods described in this specification. In some embodiments, controller 165 can use control processes to compensate for response times of one or more FRC and/or one or more MFC of the plasma processing chamber. For example, a delay in response time of the FRC can originate from lag in electronic control response and/or from a lag in gas flow from a switching valve through the FRC to the gas distribution plate. Controller 165 can compensate for these delays by anticipating a switchover point and accounting for any additional delays in response time due to FRC or MFC located within the gas flow path for the next etching process.

FIG. 6 depicts a partial control flow process 600 for the gas switching methods described in this specification. A recipe command 602 is received by a system controller 604, e.g., controller 165. Recipe command 602 can be input by a user of the plasma processing chamber, e.g., processing chamber 100, 200. A recipe command 602 can define one or more etching processes including respective etching gases to be sequentially performed on a wafer to etch a structure. The recipe command 602 can include, for example, etching gas mixtures, length of etching process, or the like. The recipe command 602 can be converted by the controller 165 to a set of control signals for corresponding components of the processing chamber 100, 200, e.g., valves, flow controllers, FRCs, MFCs, RF generators, or other components described herein, to implement the etching processes of the recipe command 602. System controller 602 can provide the control signals to the electro-valve manifold 606 operably coupled to the gas panel to actuate respective valves, e.g., MFC, in the gas panel 608 to generate a flow of the etching gas and actuate the requested switching valves 610. The gas flows through the switching valve to the gas distribution plate 612 which injects the etching gas into the processing region to establish the plasma in the processing region.

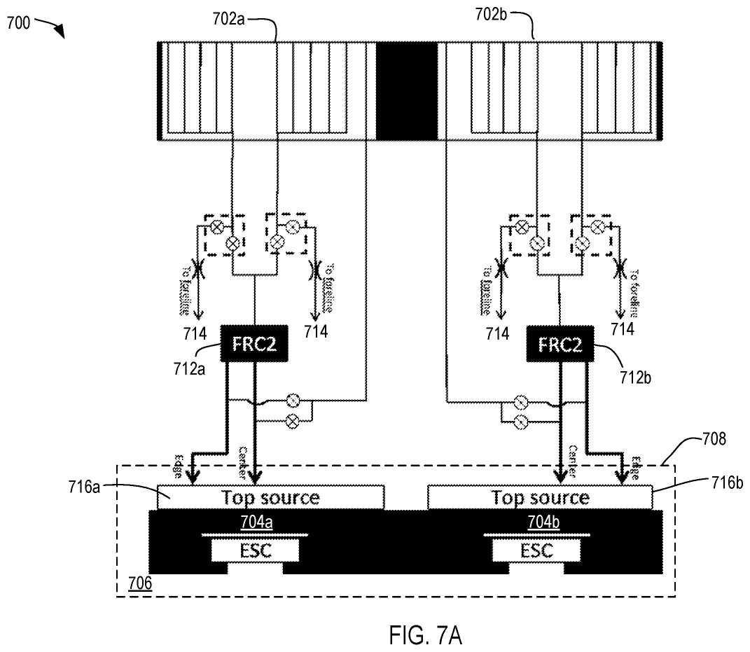

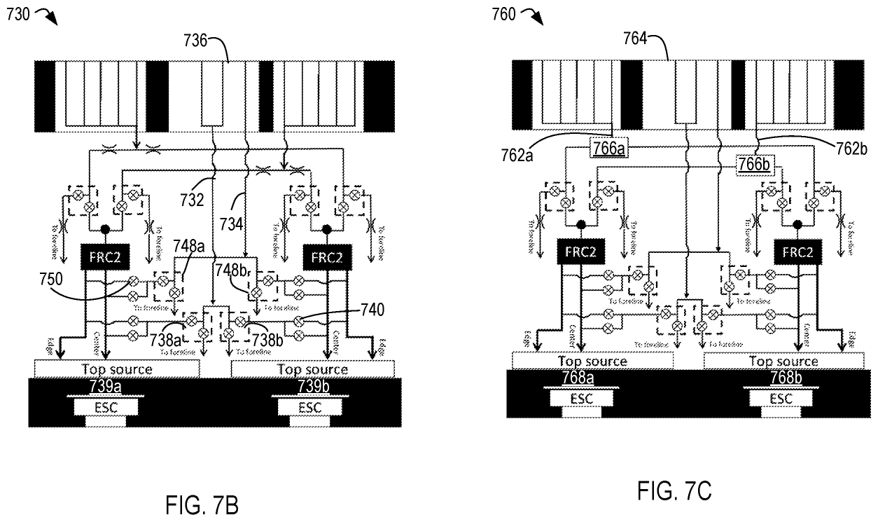

Other embodiments implementing the methods and systems described herein are possible. FIGS. 7A-7C depict example cross-sectional views of portions of various plasma processing chambers, according to some embodiments.

In some embodiments, a processing chamber can be coupled to two or more independent gas panels. FIG. 7A depicts a cross-sectional view of a portion of a processing chamber 700 including two independent gas panels 702a, 702b, where each gas panel 702a, 702b can supply process gases to respective processing regions 704a, 704b within chamber volume 706, e.g., to support processing of two or more wafers in parallel within the processing chamber 700. The two gas panels 702a, 702b are each coupled to the chamber 708 using a different gas line and through a respective inlet into the chamber body 708. The two or more gas panels 702a, 702b can include the same or different set of gas sources, e.g., different gas chemistries. Each gas panel can be coupled to a respective set of switching valves, configured as described above, to direct a first etching gas toward a respective FRC 712a, 712b or toward a vent 714 and to direct a second etching gas toward the vent 714 (e.g., a foreline) or toward FRCs 712a, 712b, where the FRCs are configured to direct the etching gas into a respective processing region 704a, 704b through gas distribution plate 716a, 716b to establish a plasma. Using separate, independent gas panels for each processing region within the chamber volume 101 can substantially reduce (e.g., minimize or eliminate) crosstalk between the two or more processing regions as well as reduce (e.g., minimize or eliminate) effects of switching etching gas in fewer than all the processing regions at a time.

In some embodiments, a processing chamber can include a switching valve manifold for one or more IGI lines for one or more of the processing regions. FIG. 7B depicts a cross-sectional view of a portion of a processing chamber 730 including two IGI lines 732, 734 each coupled to a respective injection gas source in a shared gas panel 736. IGI line 732 includes a set of switching valves 738a, 738b to switch between a vent (e.g., foreline) and directing the flow of injection gas toward a respective processing region 739a, 739b. The flow of the injection gas is divided between a center region and an edge region of the gas distribution plate, wherein each of the divided gas flow path includes a valve, e.g., valve 740. IGI line 734 includes a set of switching valves 748a, 748b to switch between a vent (e.g., foreline) and directing the flow of injection gas toward a respective processing region 739a, 739b. The flow of the injection gas is divided between a center region and an edge region of the gas distribution plate, wherein each of the divided gas flow path includes a valve, e.g., valve 750. Utilizing gas switching manifold in the IGI line(s) of the processing chamber can reduce a ramp time of the injection gas to the gas distribution plate.

In some embodiments, a processing chamber can include FRCs (e.g., MFCs working in tandem) as flow restriction nodes and to divide a flow in a first gas line and a second gas line from a shared gas panel. FIG. 7C depicts an example cross-sectional view of a portion of a processing chamber 760. Gas lines 762a, 762b, are each coupled to a shared gas panel 764. Gas line 762a is coupled to an FRC 766a configured to divide a gas flow from gas line 762a into two gas flow paths each corresponding to a respective processing region 768a, 768b. Gas line 762b is coupled to an FRC 766b configured to divide a gas flow from gas line 762b into two gas flow paths each corresponding to a respective processing region 768a, 768b.

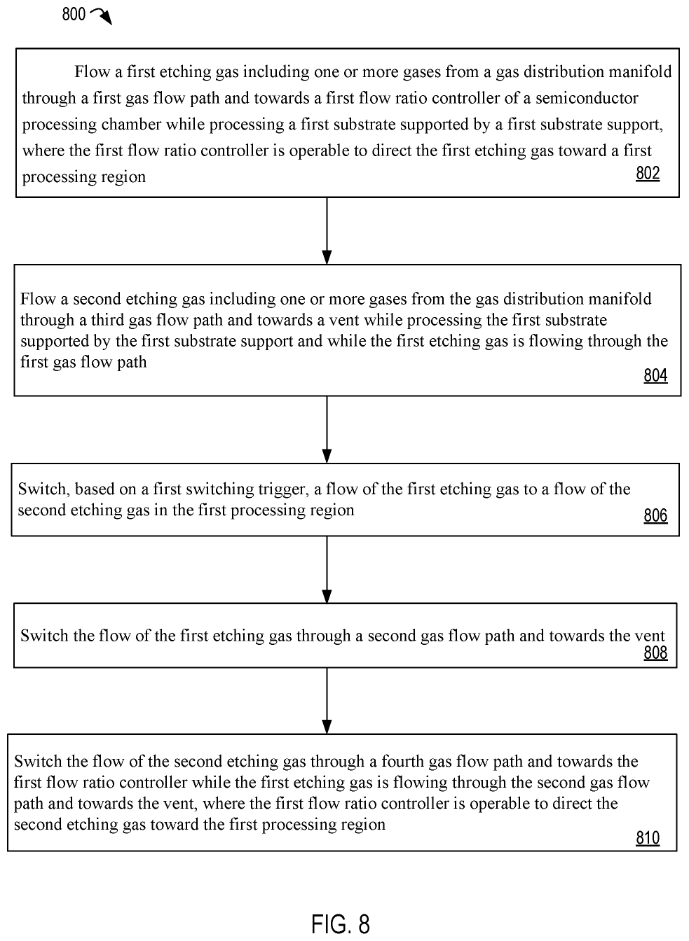

Methods for using gas switching to perform etching processes in a plasma processing chamber have been described. FIG. 8 shows a flow diagram of an example process 800 for a plasma processing chamber using gas switching. In step 802, one or more controllers (e.g., controller 165 shown in FIG. 1) provides instructions to a gas distribution manifold, e.g., gas panel 308, such that the gas distribution manifold flows a first etching gas including one or more gases through a first gas flow path, e.g., gas flow path 320, and towards a first flow ratio controller, e.g., FRC 324, of a semiconductor processing chamber while processing a first substrate, e.g., substrate 307a, supported by a first substrate support, e.g., substrate support 256. The first flow ratio controller is operable to direct the first etching gas toward a first processing region, e.g., processing region 302.

In step 804, the controller provides instructions to the gas distribution manifold, e.g., gas panel 308, such that the gas distribution manifold flows a second etching gas including one or more gases through a third gas flow path, e.g., gas flow path 332, and towards a vent, e.g., vent 336, while processing the first substrate supported by the first substrate support and while the first etching gas is flowing through the first gas flow path.

In step 806, the controller provides instructions to one or more switching valves to switch a flow of the first etching gas valves to a flow of the second etching gas in the first processing region based on a first switching trigger. Switching the flow of the first etching gas to the flow of the second etching gas includes a step 808 of switching the flow of the first etching gas through a second gas flow path 342 and towards the vent, and a step 810 of switching the flow of the second etching gas through a fourth gas flow path 344 and towards the first flow ratio controller while the first etching gas is flowing through the second gas flow path and towards the vent, where the first flow ratio controller is operable to direct the second etching gas toward the first processing region.

In some implementations, a system includes two gas lines, each divided into two paths, where each path includes a set of switching valves. Each gas line of the system is configured to couple to a gas panel through respective outlets of the gas panel. Each gas line can be configured to direct a flow of a respective etching gas including one or more gas sources from the gas panel. The gas lines are divided (e.g., split) to direct gas flow to two processing regions of a chamber coupled to the system, where each gas line is coupled to the chamber through respective inlets of the chamber. The system can further include flow restriction node(s), e.g., any flow restriction node described in this specification. Each portion of the divided gas lines directs a portion of the etching gas flow towards a respective processing region. The system further includes flow ratio controllers (FRC), where the set of switching valves corresponding to the etching gas are configured switch flow of gas between (i) vent (e.g., a foreline) and (ii) along a respective gas flow path to a corresponding FRC. The FRCs can divide (e.g., split) flow of gas along two or more flow paths. The FRCs can be configured to adjust a ratio of gas flow into each of the divided paths, for example, where a first path has less flow than a second path. The FRCs are configured to couple to the chamber where gas flow from the FRCs can be introduced into a respective processing region within the chamber volume 201 using inlets of the chamber.

Aspects of the subject matter and the actions and operations described in this specification, for example, computing devices such as controller 165 and processes performed by controller 165 such as controlling switching of etching gasses of a plasma processing chamber, can be implemented in digital electronic circuitry, in tangibly-embodied computer software or firmware, in computer hardware, including the structures disclosed in this specification and their structural equivalents, or in combinations of one or more of them.

The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech or tactile; and input from the user can be received in any form, including acoustic, speech, or tactile input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

This specification uses the term “configured to” in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system for semiconductor processing, the system comprising:
a chamber enclosing a first processing region;
a first substrate support within the chamber and configured to retain a first substrate in the first processing region of the chamber;
a gas distribution manifold, wherein the gas distribution manifold is operatively coupled to the chamber to introduce a first etching gas comprising one or more gases from the gas distribution manifold using a first inlet into the chamber and a second etching gas comprising one or more gases from the gas distribution manifold into the chamber using a second inlet;
a first gas distribution channel coupled to the first inlet and configured to selectively switch between
directing the first etching gas along a first gas flow path towards the first processing region within the chamber, and
directing the first etching gas along a second gas flow path towards a vent; and
a second gas distribution channel coupled to the second inlet and configured to selectively switch between
directing the second etching gas along a third gas flow path towards the vent, and
directing the second etching gas along a fourth gas flow path towards the first processing region within the chamber; and
a first flow ratio controller (FRC) operatively coupled to the first gas distribution channel and the second gas distribution channel and configured to direct the first etching gas and the second etching gas towards the first processing region.

2. The system of claim 1, wherein the chamber encloses a second processing region, and wherein the system further comprises:
a second substrate support within the chamber and configured to retain a second substrate in the second processing region of the chamber.

3. The system of claim 2, wherein the first gas distribution channel is further configured to selectively switch between
directing the first etching gas along a fifth gas flow path towards the second processing region, and
directing the first etching gas along a sixth gas flow path towards the vent, and wherein the second gas distribution channel is further configured to selectively switch between
directing the second etching gas along a seventh gas flow path towards the vent, and
directing the second etching gas along an eighth gas flow path towards the second processing region; and
a second flow ratio controller (FRC) operatively coupled to the first gas distribution channel and the second gas distribution channel and configured to direct the first etching gas and the second etching gas towards the second processing region.

4. The system of claim 2, wherein the gas distribution manifold comprises a first gas distribution manifold operatively coupled to the chamber, and further comprising:
a second gas distribution manifold, wherein the second gas distribution manifold is operatively coupled to the chamber to introduce a third etching gas comprising one or more gases from the second gas distribution manifold through a third inlet into the chamber and a fourth etching gas comprising one or more gases from the second gas distribution manifold into the chamber through a fourth inlet;
a third gas distribution channel coupled to the third inlet and configured to selectively switch between
directing the third etching gas along a fifth gas flow path towards the first processing region within the chamber, and
directing the third etching gas along a sixth gas flow path towards a vent; and
a fourth gas distribution channel coupled to the fourth inlet and configured to selectively switch between
directing the fourth etching gas along a seventh gas flow path towards the vent, and
directing the fourth etching gas along an eighth gas flow path towards the second processing region within the chamber; and
a second flow ratio controller (FRC) operatively coupled to the first gas distribution channel and the second gas distribution channel and configured to direct the first etching gas or the second etching gas towards the second processing region.

5. The system of claim 2, wherein the first processing region and the second processing region comprise separately controllable process plasmas.

6. The system of claim 1, wherein the first etching gas comprises two or more gases, and the second etching gas comprises two or more different gases.

7. The system of claim 1, wherein the first etching gas comprises an oxide-based etching gas and the second etching gas comprises a nitride-based etching gas.

8. The system of claim 3, further comprising:
a first gas distribution plate operatively coupled to the first FRC and a second gas distribution plate operatively coupled to the second FRC, wherein each of the first and second gas distribution plates comprises a plurality of openings for directing the first etching gas or the second etching gas towards the first substrate or the second substrate, respectively, and
wherein the first and second gas distribution plates are configured to deliver a first gas flow rate to an edge and a second gas flow rate to a center of the first and second substrates, respectively.

9. The system of claim 3, further comprising one or more first flow restriction nodes arranged with respect to the first gas distribution channel to restrict gas flow of the first etching gas along the first gas flow path and/or the fifth gas flow path.

10. The system of claim 9, further comprising one or more second flow restriction nodes arranged with respect to the second gas distribution channel to restrict gas flow of the second etching gas along the fourth gas flow path and the eighth gas flow path.

11. The system of claim 10, wherein the one or more first flow restriction nodes and the one or more second flow restriction nodes are operable to maintain a threshold flow of gas in the first gas distribution channel and the second gas distribution channel, respectively, for a period of time including a switch between flow of the first etching gas and the second etching gas.

12. The system of claim 3, wherein the first gas distribution channel comprises a first set of switching valves and a second set of switching valves configured to independently switch between
a flow of the first etching gas toward the first processing region, and a flow of the second etching gas toward the vent, and
a flow of the first etching gas toward the second processing region and a flow of the second etching gas toward the vent, respectively.

13. The system of claim 12, wherein the second gas distribution channel comprises a third set of switching valves and a fourth set of switching valves configured to independently switch between
a flow of the of the second etching gas toward the first processing region, and a flow of the first etching gas toward the vent, and
a flow of the second etching gas toward the second processing region and a flow of the first etching gas toward the vent, respectively.

14. The system of claim 13, wherein a distance between the first set of switching valves and the third set of switching valves from the first FRC is minimized.

15. The system of claim 14, wherein a distance between the second set of valves and the fourth set of valves from the second FRC is minimized.

16. The system of claim 15, wherein a stabilization time to establish a threshold pressure of the second etching gas after switching between flow of the first etching gas and the second etching gas comprises less than about 2 seconds.

17. The system of claim 1, further comprising, a gas injection channel operatively coupled to the gas distribution manifold and configured to direct an injection gas toward the first processing region, wherein the gas injection channel comprises a first injection flow to an edge region and a second injection flow to a center region of the first substrate support.

18. A method of semiconductor processing, comprising:
flowing a first etching gas including one or more gases from a gas distribution manifold through a first gas flow path and towards a first flow ratio controller of a semiconductor processing chamber while processing a first substrate supported by a first substrate support, wherein the first flow ratio controller is operable to direct the first etching gas toward a first processing region;
flowing a second etching gas including one or more gases from the gas distribution manifold through a third gas flow path and towards a vent while processing the first substrate supported by the first substrate support and while the first etching gas is flowing through the first gas flow path; and
switching, based on a first switching trigger, a flow of the first etching gas to a flow of the second etching gas in the first processing region comprising:
switching the flow of the first etching gas through a second gas flow path and towards the vent; and
switching the flow of the second etching gas through a fourth gas flow path and towards the first flow ratio controller while the first etching gas is flowing through the second gas flow path and towards the vent, wherein the first flow ratio controller is operable to direct the second etching gas toward the first processing region.

19. The method of claim 18, further comprising:
flowing the first etching gas including one or more gases from the gas distribution manifold through a fifth gas flow path and towards a second flow ratio controller of the semiconductor processing chamber while processing a second substrate supported by a second substrate support, wherein the second flow ratio controller is operable to direct the first etching gas toward a second processing region;
flowing the second etching gas including one or more gases from the gas distribution manifold through a sixth gas flow path and towards the vent while processing the second substrate supported by the second substrate support and while the first etching gas is flowing through the fifth gas flow path; and
switching, based on a second switching trigger, a flow of the first etching gas to a flow of the second etching gas in the second processing region comprising:
switching the flow of the first etching gas through a seventh gas flow path and towards the vent; and
switching the flow of the second etching gas through an eighth gas flow path and towards the second flow ratio controller while the first etching gas is flowing through the seventh gas flow path and towards the vent, wherein the second flow ratio controller is operable to direct the second etching gas toward the second processing region.

20. The method of claim 19, further comprising:
receiving sensor data indicative of one or more characteristics of respective surfaces of the first substrate and the second substrate;
in response to determining the first switching trigger is met based on the sensor data of the one or more characteristics of the surface of the first substrate, performing the switching of the flow of the first etching gas and the flow of the second etching gas for the first processing region; and
in response to determining the second switching trigger is not met based the sensor data of the one or more characteristics of the surface of the second substrate, maintaining the flow of the first etching gas and the flow of the second etching gas for the second processing region.
